(19) United States
(12) Patent Application Publication
(10) Pub. No.: US 2025/0248054 A1
(43) Pub. Date: Jul. 31, 2025

(54) SEMICONDUCTOR DEVICE AND METHOD OF MANUFACTURING THE SAME

(71) Applicant: NANYA TECHNOLOGY CORPORATION, New Taipei city (TW)

(72) Inventor: Hsu CHIANG, New Taipei City (TW)

(21) Appl. No.: 18/428,119

(22) Filed: Jan. 31, 2024

(51) Int. Cl. H01L 21/768; H01L 23/528; H10B 12/00

(52) U.S. Cl. CPC H10D 1/68; H01L 21/76877; H01L 23/528; H10B 12/00

(57) ABSTRACT

The present disclosure provides a semiconductor device. The semiconductor device includes a conductive layer, a landing pad, a capacitor, and an interlayer contact. The conductive layer has a trench. The landing pad is filled in the trench. The capacitor is disposed over the landing pad. The interlayer contact is connected between the landing pad and the capacitor. A width of a top of the interlayer contact is greater than a width of the capacitor.

### BACKGROUND

### Field of Invention

The present disclosure relates to a semiconductor device and a method of manufacturing the same.

### Description of Related Art

With the evolution of generations of semiconductor processes, there will be challenges of a semiconductor structure in a memory device. Regarding semiconductor devices, the process related to dynamic-random access memory (DRAM) is pivotal, because it determines the performance of the semiconductor devices. For instance, the size of the capacitor deposited on the landing pad becomes larger to gain more capacitance.

However, the miss landing of the capacitor brings out the function or reliability fail of the semiconductor devices. More specifically, the capacitor with greater width may cover the landing pad and be contact with bit lines, thereby causing deterioration of electrical performance of the semiconductor devices (for example, the leakage current problem).

Therefore, how to propose a semiconductor device and a method of manufacturing the same that can improve the electrical performance of the semiconductor device is one of the problems that the industry is eager to invest in research and development resources to solve.

### SUMMARY

In view of this, one purpose of present disclosure is to provide a semiconductor device and a method of manufacturing the same that can solve the aforementioned problems.

In order to achieve the above objective, according to an embodiment of the present disclosure, the semiconductor device includes a conductive layer, a landing pad, a capacitor, and an interlayer contact. The conductive layer has a trench. The landing pad is filled in the trench. The capacitor is disposed over the landing pad. The interlayer contact is connected between the landing pad and the capacitor. A width of a top of the interlayer contact is greater than a width of the capacitor.

In one or more embodiments of the present disclosure, the semiconductor device further comprises a dielectric layer covers the conductive layer and the landing pad.

In one or more embodiments of the present disclosure, a top surface of the dielectric layer and a top surface of the interlayer contact are coplanar.

In one or more embodiments of the present disclosure, a bottom surface of the interlayer contact is lower than a top surface of the landing pad with a distance.

In one or more embodiments of the present disclosure, a width of a bottom of the interlayer contact is less than a width of a top of the landing pad.

In one or more embodiments of the present disclosure, the width of the top of the interlayer contact is greater than the width of the bottom of the interlayer contact.

In one or more embodiments of the present disclosure, a width of a top of the landing pad is greater than a width of a bottom of the landing pad.

In one or more embodiments of the present disclosure, the semiconductor device further comprises a contact material filled in the trench and located below the landing pad.

In order to achieve the above objective, according to an embodiment of the present disclosure, the semiconductor device includes a conductive layer, a landing pad, a capacitor, and an interlayer contact. The conductive layer has a trench. The landing pad is filled in the trench. The capacitor is disposed over the landing pad. The interlayer contact is connected between the landing pad and the capacitor. A width of the interlayer contact tapers downward.

In one or more embodiments of the present disclosure, the semiconductor device further comprises a dielectric layer covers the conductive layer and the landing pad.

In one or more embodiments of the present disclosure, a top surface of the dielectric layer and a top surface of the interlayer contact are coplanar.

In one or more embodiments of the present disclosure, a bottom surface of the interlayer contact is lower than a top surface of the landing pad with a distance.

In one or more embodiments of the present disclosure, a width of a top of the interlayer contact is greater than a width of the capacitor.

In one or more embodiments of the present disclosure, a width of a top of the landing pad is less than a width of the capacitor.

In one or more embodiments of the present disclosure, a width of a bottom of the interlayer contact is less than a width of a top of the landing pad.

In one or more embodiments of the present disclosure, a width of a top of the landing pad is greater than a width of a bottom of the landing pad.

In one or more embodiments of the present disclosure, the semiconductor device further comprises a contact material filled in the trench and located below the landing pad.

In order to achieve the above objective, according to an embodiment of the present disclosure, a method of manufacturing a semiconductor device includes: sequentially forming a conductive layer, a contact material, a landing pad, and a dielectric layer, in which the contact material and the landing pad are filled in a trench of the conductive layer and the landing pad overfills the trench, and in which the dielectric layer covers the conductive layer and the landing pad; forming a recess on a top surface of the dielectric layer to expose the landing pad; forming an interlayer contact filling the recess; and forming a capacitor on the interlayer contact.

In one or more embodiments of the present disclosure, forming the recess on the top surface of the dielectric layer such that a portion of the landing pad is removed.

In one or more embodiments of the present disclosure, forming a capacitor on the interlayer contact such that a width of the capacitor is less than a width of a top of the interlayer contact.

In summary, the semiconductor device and the method of manufacturing the same of the present disclosure provides a structure that the capacitor well connecting to the landing pad by the interlayer contact. In the semiconductor device and the method of manufacturing the same of the present disclosure, since the interlayer contact is formed between the landing pad and the capacitor, the interlayer contact may be formed adjustable to prevent the capacitor from contacting the conductive layer. In the semiconductor device and the method of manufacturing the same of the present disclosure, since the width of the top of the interlayer contact is greater than the width of the capacitor, the interlayer contact may be configured as a stop layer of the capacitor and be formed to connected between the capacitor and the landing pad without miss landing on the landing pad. To sum up, the semiconductor device and the method of manufacturing the same of the present disclosure improves the overall electrical performance of the entire semiconductor device.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a flow chart of a method of manufacturing a semiconductor device in accordance with an embodiment of present disclosure;

FIG. 2 is a cross-sectional view of an intermediate stage of manufacturing a semiconductor device in accordance with an embodiment of present disclosure;

FIG. 3 is a cross-sectional view of an intermediate stage of manufacturing the semiconductor device in accordance with another embodiment of present disclosure;

FIG. 4 is a cross-sectional view of an intermediate stage of manufacturing the semiconductor device in accordance with an embodiment of present disclosure; and

FIG. 5 is a cross-sectional view of an intermediate stage of manufacturing the semiconductor device in accordance with an embodiment of present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

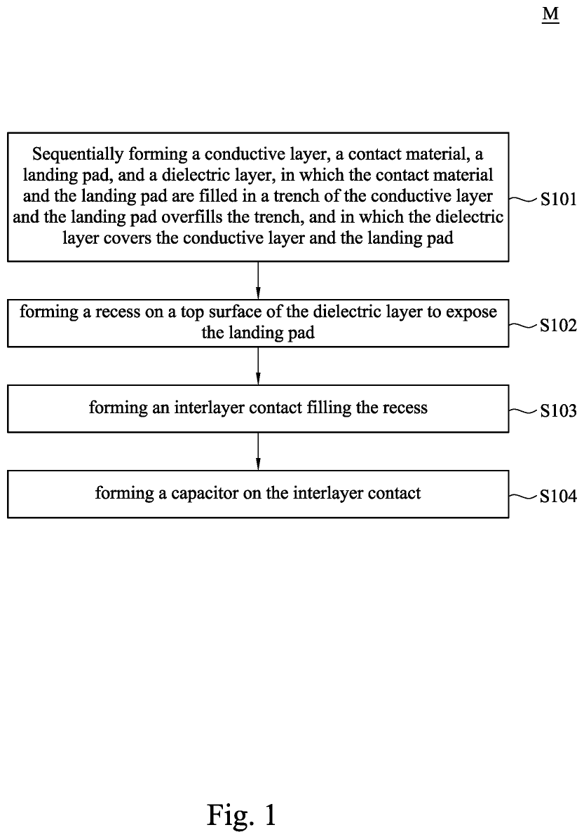

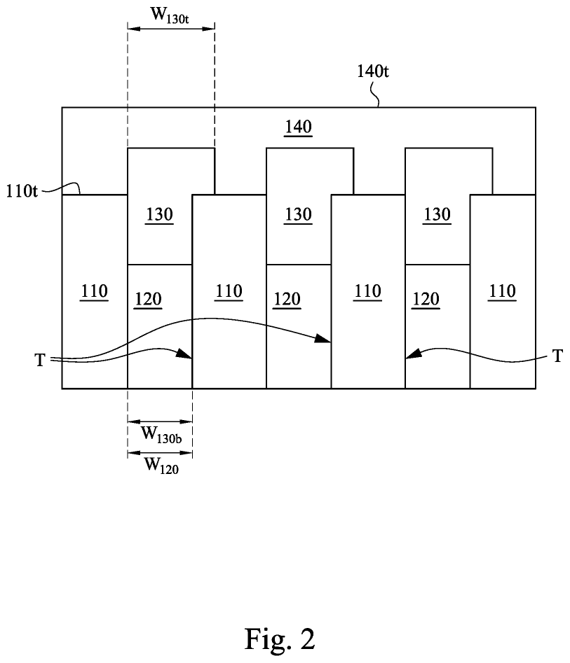

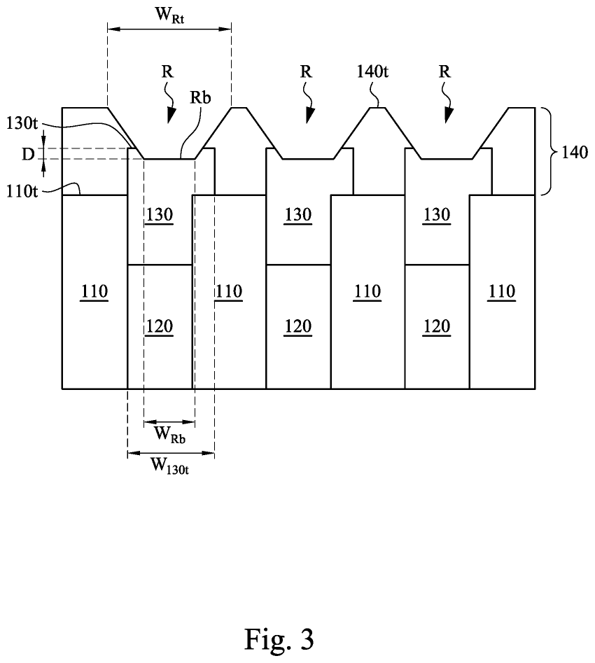

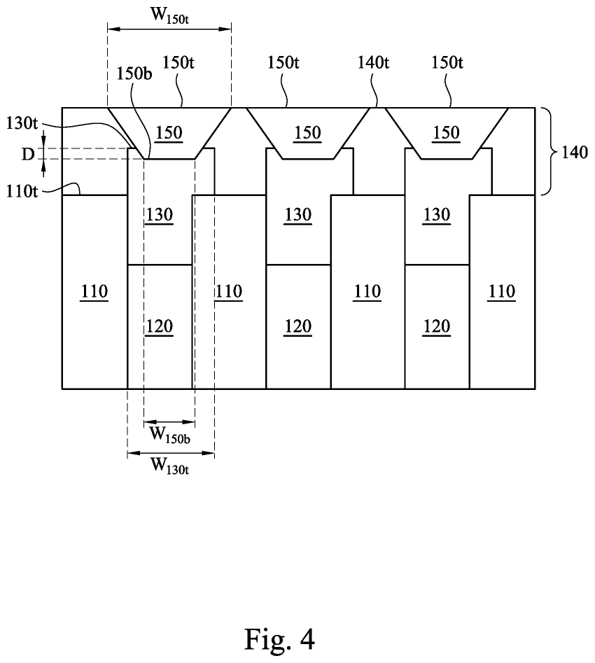

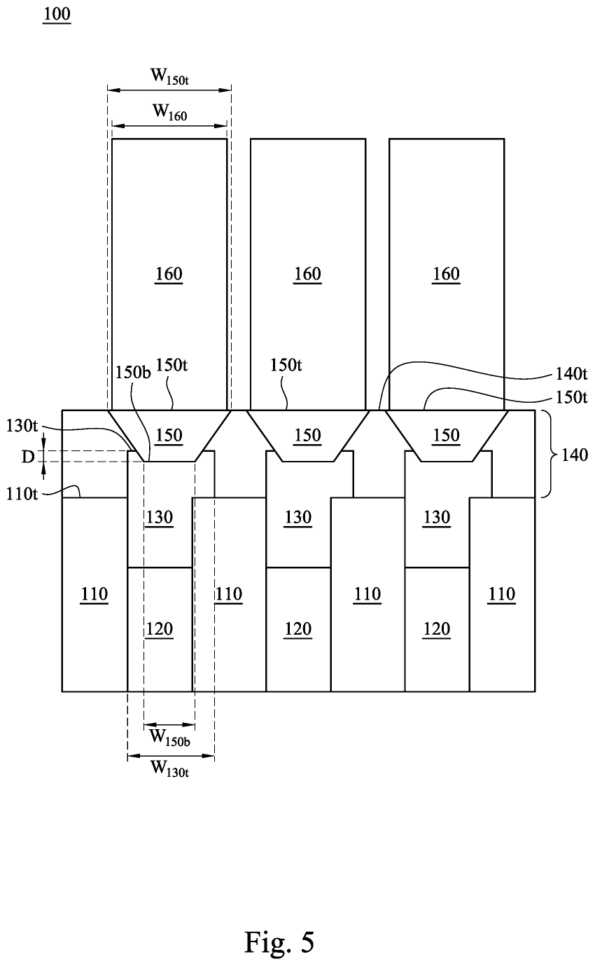

Reference is made to FIG. 1. FIG. 1 is a flow chart of a method M of manufacturing a semiconductor device 100 as shown in FIG. 6 and a semiconductor device 100 as shown in FIG. 5 in accordance with an embodiment of present disclosure. The method M shown in FIG. 1 includes a step S101, a step S102, a step S103, and a step S104. Please refer to FIG. 1 and FIG. 2 for better understanding the step S101, refer to FIG. 1 and FIG. 3 for better understanding the step S102, refer to FIG. 1 and FIG. 4 for better understanding the step S103, and refer to FIG. 1 and FIG. 5 for better understanding the step S104.

Step S101, step S102, step S103, and step S104 are described in detail below.

In step S101, a conductive layer 110, a contact material 120, a landing pad 130, and a dielectric layer 140 are sequentially formed, as shown in FIG. 2.

Reference is made to FIG. 2. FIG. 2 is a cross-sectional view of an intermediate stage of manufacturing the semiconductor device 100 in accordance with an embodiment of the present disclosure. As shown in FIG. 2, a conductive layer 110, a contact material 120, a landing pad 130, and a dielectric layer 140 are provided. In this embodiment, the conductive layer 110 has a plurality of trenches T. The contact material 120 is filled in the trenches T of the conductive layer 110. The landing pad 130 is disposed on the contact material 120 (that is, the contact material 120 is located below the landing pad 130). In some embodiments, the contact material 120 and the landing pad 130 are filled in the trenches T of the conductive layer 110. In some embodiments, the landing pad 130 overfills the trenches T of the conductive layer 110. In some embodiments, the landing pad 130 overfills the trenches T, so that a portion of the landing pad 130 is located on the conductive layer 110. The dielectric layer 140 covers the conductive layer 110 and the landing pad 130. In some embodiments, the dielectric layer 140 covers the landing pad 130, so that the landing pad 130 is not exposed.

As shown in FIG. 2, in some embodiments, the conductive layer 110 has a top surface 110t, and the dielectric layer 140 has a top surface 140t. In some embodiments, the top surface 140t of the dielectric layer 140 is higher than the landing pad 130 and the top surface 110t of the conductive layer 110.

As shown in FIG. 2, in some embodiments, the contact material 120 further has a width W₁₂₀. In some embodiments, the landing pad 130 further has a width W₁₃₀ₜ on a top of the landing pad 130 and a width W_{130b} on a bottom of the landing pad 130. In some embodiments, the width W₁₂₀ of the contact material 120 is substantially equal to the width W_{130b} of the bottom of the landing pad 130. In some embodiments, the width W₁₃₀ₜ of the top of the landing pad 130 is substantially greater than the width W_{130b} of the bottom of the landing pad 130.

In some embodiments, the conductive layer 110 is configured as portions of bit lines of the DRAM. In some embodiments, the conductive layer 110 may include a material, such as polysilicon, metallic material, nitride, or the like. However, any suitable material may be utilized.

In some embodiments, the conductive layer 110 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electrochemical plating), electroless plating, or the like. The present disclosure is not intended to limit the methods of forming the conductive layer 110.

In some embodiments, the contact material 120 may be composed of oxide. In some embodiments, the contact material 120 may include a material, such as polysilicon, or the like. However, any suitable material may be utilized.

In some embodiments, the contact material 120 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electrochemical plating), electroless plating, or the like. The present disclosure is not intended to limit the methods of forming the contact material 120.

In some embodiments, the landing pad 130 may be composed of conductive material. In some embodiments, the landing pad 130 may be composed of metallic material. In some embodiments, the landing pad 130 may include a material, such as tungsten (W), or the like. However, any suitable material may be utilized.

In some embodiments, the landing pad 130 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electrochemical plating), electroless plating, or the like. The present disclosure is not intended to limit the methods of forming the landing pad 130.

In some embodiments, the dielectric layer 140 may be composed of nitride. In some embodiments, the dielectric layer 140 may include a material, such as titanium nitride (TiN), silicon nitride (SiₓN_{y}), or the like. However, any suitable material may be utilized.

In some embodiments, the dielectric layer 140 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electrochemical plating), electroless plating, or the like. The present disclosure is not intended to limit the methods of forming the dielectric layer 140.

In some embodiments, the trenches T may be formed by any suitable method, for example, wet etching, dry etching, or the like. The present disclosure is not intended to limit the methods of forming the trench T.

In step S102, a recess R is formed on a top surface 140t of the dielectric layer 140, as shown in FIG. 3.

Reference is made to FIG. 3. FIG. 3 is a cross-sectional view of an intermediate stage of manufacturing the semiconductor device 100 in accordance with an embodiment of the present disclosure. In this embodiment, a recess R is formed on a top surface 140t of the dielectric layer 140 to expose the landing pad 130. As shown in FIG. 3, in some embodiments, a portion of the dielectric layer 140 is removed, so that the recess R is formed in situ. The recess R has a bottom surface Rb, and the landing pad 130 has a top surface 130t. In some embodiments, the bottom surface Rb of the recess R is lower than the top surface 130t of the landing pad 130. In some embodiments, the bottom surface Rb is lower than the top surface 130t with a distance D, as shown in FIG. 3. More specifically, a portion of the landing pad 130 is removed during performing step S102, such that the bottom surface Rb is lower than the top surface 130t with a distance D, as shown in FIG. 3.

As shown in FIG. 3, in some embodiments, the recess R further has a width W_{Rt} on a top of the recess R and a width W_{Rb} on a bottom of the recess R. In some embodiments, the width W_{Rt} of the top of the recess R is substantially greater than the width W_{Rb} of the bottom of the recess R. In some embodiments, the width W_{Rb} of the bottom of the recess R is substantially less than the width W₁₃₀ₜ of the top of the landing pad 130. In some embodiments, the width W_{Rt} of the top of the recess R is substantially greater than the width W₁₃₀ₜ of the top of the landing pad 130. In some embodiments, the width of the recess R tapers downward, as shown in FIG. 3.

In step S103, an interlayer contact 150 is formed and fills the recess R, as shown in FIG. 4.

Reference is made to FIG. 4. FIG. 4 a cross-sectional view of an intermediate stage of manufacturing the semiconductor device 100 in accordance with an embodiment of the present disclosure. In this embodiment, an interlayer contact 150 is formed and fills the recess R. As shown in FIG. 4, the interlayer contact 150 is located over the dielectric layer 140. More specifically, the interlayer contact 150 is formed filling the recess R, such that the interlayer contact 150 is in contact with the landing pad 130. In some embodiments, the interlayer contact 150 filling the recess R further has a top surface 150t, and the top surface 150t of the interlayer contact 150 and the top surface 140t of the dielectric layer 140 are coplanar.

In some embodiments, the method M further comprises planarizing the interlayer contact 150. The step of planarizing the interlayer contact 150 is performed after performing step S103. More specifically, the interlayer contact 150 overfills the recess R on the dielectric layer 140 during performing step S103 and then planarized, such that the top surface 150t of the interlayer contact 150 is formed accordingly, as shown in FIG. 4. In some embodiments, planarizing the interlayer contact 150 is performed such that the top surface 150t of the interlayer contact 150 is levelled with the top surface 140t of the dielectric layer 140, as shown in FIG. 4.

In some embodiments, the interlayer contact 150 is planarized by chemical mechanical process (CMP), for example. The present disclosure is not intended to limit the method of planarizing the interlayer contact 150.

As shown in FIG. 4, in some embodiments, the interlayer contact 150 further has a bottom surface 150b. In some embodiments, the bottom surface 150b of the interlayer contact 150 is lower than the top surface 130t of the landing pad 130. In some embodiments, the bottom surface 150b is lower than the top surface 130t with a distance D, as shown in FIG. 4.

As shown in FIG. 4, in some embodiments, the interlayer contact 150 further has a width W₁₅₀ₜ on a top of the interlayer contact 150 and a width W_{150b} on a bottom of the interlayer contact 150. In some embodiments, the width W₁₅₀ₜ of the top of the interlayer contact 150 is substantially greater than the width W_{150b} of the bottom of the interlayer contact 150. In some embodiments, the width W_{150b} of the bottom of the interlayer contact 150 is substantially less than the width W₁₃₀ₜ of the top of the landing pad 130. In some embodiments, the width W₁₅₀ₜ of the top of the interlayer contact 150 is substantially greater than the width W₁₃₀ₜ of the top of the landing pad 130. In some embodiments, the width of the interlayer contact 150 tapers downward, as shown in FIG. 4.

In some embodiments, the interlayer contact 150 may be composed of conductive material. In some embodiments, the landing pad 130 may be composed of metallic material. In some embodiments, the interlayer contact 150 may include a material, such as tungsten (W), titanium (Ti), titanium nitride (TiN), or the like. However, any suitable material may be utilized.

In some embodiments, the interlayer contact 150 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electrochemical plating), electroless plating, or the like. The present disclosure is not intended to limit the methods of forming the interlayer contact 150.

In step S104, a capacitor 160 is formed on the interlayer contact 150, as shown in FIG. 5.

Reference is made to FIG. 5. FIG. 5 a cross-sectional view of an intermediate stage of manufacturing the semiconductor device 100 in accordance with an embodiment of the present disclosure. In this embodiment, the capacitor 160 is disposed over the landing pad 130. More specifically, the capacitor 160 is formed on the interlayer contact 150, such that the interlayer contact 150 is connected between the landing pad 130 and the capacitor 160. After the step S104 is performed, the semiconductor device 100 is formed.

As shown in FIG. 5, in some embodiments, the capacitor 160 has a width W₁₆₀. In some embodiments, the capacitor 160 is formed on the interlayer contact 150, such that the width W₁₅₀ₜ of the top of the interlayer contact 150 is substantially greater than the width W₁₆₀ of the capacitor 160. In some embodiments, the width W₁₃₀ₜ of the top of the landing pad 130 is substantially less than the width W₁₆₀ of the capacitor 160.

In some embodiments, the capacitor 160 may be composed of conductive material. In some embodiments, the capacitor 160 may be composed of metallic material. In some embodiments, the capacitor 160 may include a material, such as titanium (Ti), or the like. However, any suitable material may be utilized.

In some embodiments, the capacitor 160 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electrochemical plating), electroless plating, or the like. The present disclosure is not intended to limit the methods of forming the capacitor 160.

By performing the method M shown in FIG. 1 of the present disclosure, the semiconductor device 100 with better electrical performance may be formed.

Based on the above discussions, it can be seen that the semiconductor device and the method of manufacturing the same of the present disclosure provides a structure that the capacitor well connecting to the landing pad by the interlayer contact. In the semiconductor device and the method of manufacturing the same of the present disclosure, since the interlayer contact is formed between the landing pad and the capacitor, the interlayer contact may be formed adjustable to prevent the capacitor from contacting the conductive layer. In the semiconductor device and the method of manufacturing the same of the present disclosure, since the width of the top of the interlayer contact is greater than the width of the capacitor, the interlayer contact may be configured as a stop layer of the capacitor and be formed to connected between the capacitor and the landing pad without miss landing on the landing pad. To sum up, the semiconductor device and the method of manufacturing the same of the present disclosure improves the overall electrical performance of the entire semiconductor device.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor device, comprising:
a conductive layer having a trench;
a landing pad filled in the trench;
a capacitor disposed over the landing pad; and
an interlayer contact connected between the landing pad and the capacitor, wherein a width of a top of the interlayer contact is greater than a width of the capacitor.

2. The semiconductor device of claim 1, further comprising a dielectric layer covering the conductive layer and the landing pad.

3. The semiconductor device of claim 2, wherein a top surface of the dielectric layer and a top surface of the interlayer contact are coplanar.

4. The semiconductor device of claim 1, wherein a bottom surface of the interlayer contact is lower than a top surface of the landing pad with a distance.

5. The semiconductor device of claim 1, wherein a width of a bottom of the interlayer contact is less than a width of a top of the landing pad.

6. The semiconductor device of claim 5, wherein the width of the top of the interlayer contact is greater than the width of the bottom of the interlayer contact.

7. The semiconductor device of claim 1, wherein a width of a top of the landing pad is greater than a width of a bottom of the landing pad.

8. The semiconductor device of claim 1, further comprising a contact material filled in the trench and located below the landing pad.

9. A semiconductor device, comprising:
a conductive layer having a trench;
a landing pad filled in the trench;
a capacitor disposed over the landing pad; and
an interlayer contact connected between the landing pad and the capacitor, wherein a width of the interlayer contact tapers downward.

10. The semiconductor device of claim 9, further comprising a dielectric layer covering the conductive layer and the landing pad.

11. The semiconductor device of claim 10, wherein a top surface of the dielectric layer and a top surface of the interlayer contact are coplanar.

12. The semiconductor device of claim 9, wherein a bottom surface of the interlayer contact is lower than a top surface of the landing pad with a distance.

13. The semiconductor device of claim 9, wherein a width of a top of the interlayer contact is greater than a width of the capacitor.

14. The semiconductor device of claim 13, wherein a width of a top of the landing pad is less than a width of the capacitor.

15. The semiconductor device of claim 9, wherein a width of a bottom of the interlayer contact is less than a width of a top of the landing pad.

16. The semiconductor device of claim 9, wherein a width of a top of the landing pad is greater than a width of a bottom of the landing pad.

17. The semiconductor device of claim 9, further comprising a contact material filled in the trench and located below the landing pad.

18. A method of manufacturing a semiconductor device, comprising:
sequentially forming a conductive layer, a contact material, a landing pad, and a dielectric layer, in which the contact material and the landing pad are filled in a trench of the conductive layer and the landing pad overfills the trench, and in which the dielectric layer covers the conductive layer and the landing pad;
forming a recess on a top surface of the dielectric layer to expose the landing pad;
forming an interlayer contact filling the recess; and
forming a capacitor on the interlayer contact.

19. The method of claim 18, wherein forming the recess on the top surface of the dielectric layer such that a portion of the landing pad is removed.

20. The method of claim 18, wherein forming a capacitor on the interlayer contact such that a width of the capacitor is less than a width of a top of the interlayer contact.
